(19) United States
(12) Patent Application Publication
(10) Pub. No.: US 2025/0070008 A1
(43) Pub. Date: Feb. 27, 2025

(54) ELECTRICAL COMPONENT AND METHOD OF FORMING SAME

(71) Applicants: MEDTRONIC, INC., Minneapolis, MN (US); Samtec, Inc., New Albany, IN (US)

(72) Inventors: Caian Qiu, Chandler, AZ (US); David A. Ruben, Mesa, AZ (US); Neha M. Patel, Chandler, AZ (US); Patrick W. Kinzie, Glendale, AZ (US); Tom Hammann, New Albany, IN (US); Chris Bohn, New Albany, IN (US)

(21) Appl. No.: 18/725,118

(22) PCT Filed: Dec. 27, 2022
(86) PCT No.: PCT/US2022/054067

§ 371 Date: Jun. 27, 2024

Related U.S. Application Data
(60) Provisional application No. 63/294,185, filed on Dec. 28, 2021.

(51) Int. Cl. H01L 23/498; H01L 21/48

(52) U.S. Cl. CPC H01L 23/49827; H01L 21/486; H01L 23/49866

(57) ABSTRACT

Various embodiments of an electrical component and a method of forming such electrical component are disclosed. The electrical component includes a substrate and one or more corrosion-resistant vias Each of the one or more corrosion-resistant vias includes one or more sidewalls formed by the substrate an interface layer disposed on at least a portion of the one or more sidewalls, and gold alloy bonded to the interface layer.

### CROSS-REFERENCE TO RELATED APPLICATION

This application claims the benefit of U.S. Provisional Application No. 63/294,185, filed Dec. 28, 2021, the disclosure of which is incorporated by reference herein in its entirety.

### TECHNICAL FIELD

This disclosure generally relates to electrical components for hermetically sealed devices.

### BACKGROUND

Various systems require electrical coupling between electrical devices disposed within a sealed enclosure or housing and devices or systems external to the enclosure. Oftentimes, such electrical coupling needs to withstand various environmental factors such that a conductive pathway or pathways from the external surface of the enclosure to within the enclosure remains stable. For example, implantable medical devices (IMDs), e.g., cardiac pacemakers, defibrillators, neurostimulators, and drug pumps, which include electronic circuitry and one or more power sources, require an enclosure or housing to contain and seal these elements within a body of a patient. Many of these IMDs include one or more electrical components such as, for example, feedthrough assemblies to provide electrical connections between the elements contained within the housing and components of the IMD external to the housing, for example, one or more sensors, electrodes, and lead wires mounted on an exterior surface of the housing, or electrical contacts housed within a connector header, which is mounted on the housing to provide coupling for one or more implantable leads. Existing electrical components may include a substrate that includes vias filled with copper-based alloys.

### SUMMARY

The techniques of this disclosure generally relate to corrosion-resistant vias in a substrate. Such vias include an interface layer disposed on a sidewall of each of the vias. Additionally, the vias are filled with a gold alloy capable of bonding to the interface layer. Such via fill materials including the interface layer and gold alloy may exhibit increased corrosion resistance and reduced porosity relative to existing conductive via fill materials such as, for example, copper-alloys, or other materials susceptible to corrosion. Accordingly, electrical components formed according to the methods described herein may allow the construction of packages that have increased corrosion resistance and long-term hermeticity.

In one example, aspects of this disclosure relate to a method of forming an electrical component. The method includes providing a substrate and forming one or more vias in the substrate. Each of the one or more vias includes an opening at an outer surface of the substrate and a sidewall. The method further includes forming an interface layer on at least a portion of the sidewall of each of the one or more vias and disposing gold alloy in the one or more vias or on the outer surface of the substrate proximal to the one or more vias. The method further includes reflowing the gold alloy into the one or more vias to form one or more corrosion-resistant vias such that the interface layer is disposed between the gold alloy and the sidewall of each of the one or more vias.

In another example, aspects of this disclosure relate to an electrical component. The electrical component includes a substrate and one or more corrosion-resistant vias. The substrate includes an outer surface. The one or more corrosion-resistant vias are disposed in the substrate. Each of the one or more corrosion-resistant vias include a sidewall formed by the substrate and an opening at the outer surface of the substrate. The interface layer is disposed on at least a portion of the sidewall of each of the one or more corrosion-resistant vias. The gold alloy is bonded to the interface layer.

All headings provided herein are for the convenience of the reader and should not be used to limit the meaning of any text that follows the heading, unless so specified.

The terms “comprises” and variations thereof do not have a limiting meaning where these terms appear in the description and claims. Such terms will be understood to imply the inclusion of a stated step or element or group of steps or elements but not the exclusion of any other step or element or group of steps or elements.

In this application, terms such as “a,” “an,” and “the” are not intended to refer to only a singular entity but include the general class of which a specific example may be used for illustration. The terms “a,” “an,” and “the” are used interchangeably with the term “at least one.” The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise.

The term “and/or” means one or all of the listed elements or a combination of any two or more of the listed elements.

As used herein in connection with a measured quantity, the term “about” refers to that variation in the measured quantity as would be expected by the skilled artisan making the measurement and exercising a level of care commensurate with the objective of the measurement and the precision of the measuring equipment used. Herein, “up to” a number (e.g., up to 50) includes the number (e.g., 50).

Also herein, the recitations of numerical ranges by endpoints include all numbers subsumed within that range as well as the endpoints (e.g., 1 to 5 includes 1, 1.5, 2, 2.75, 3, 3.80, 4, 5, etc.)

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF DRAWINGS

FIG. 1 is a schematic cross-sectional view of a portion of an apparatus.

FIGS. 2-10 are schematic cross-sectional diagrams depicting various stages of a method or process for forming an electrical component including a substrate, one or more vias in the substrate, and a gold alloy disposed in the one or more vias and bonded to a sidewall of each of the one or more vias.

FIG. 2 is a schematic cross-sectional view of a provided substrate.

FIG. 3 is a schematic cross-sectional view of vias formed in the substrate of FIG. 2.

FIG. 4 is a schematic cross-section view of an interface layer disposed on the sidewall of the vias of FIG. 3.

FIG. 5 is a schematic cross-section view of a gold alloy being disposed on the substrate of FIG. 4 in the form of a bump array.

FIGS. 6-8 are schematic cross-section views of the gold alloy being disposed on the substrate of FIG. 4 using a screen-printed alloy paste that includes the gold alloy.

FIG. 6 is a schematic cross-sectional view of the substrate of FIG. 4 with a stencil and alloy paste dispensed prior to being pulled across the stencil.

FIG. 7 is a schematic cross-sectional view of the substrate of FIG. 6 after the alloy paste has been pulled across the stencil.

FIG. 8 is a schematic cross-sectional view of the substrate of FIG. 7 after the stencil has been removed leaving the paste on designated portions of the substrate or in the vias.

FIG. 9 is a schematic cross-sectional view of the substrate of FIG. 4 with alloy paste dispensed in the one or more vias and on an outer surface of the substrate proximal to the one or more vias.

FIG. 10 is a schematic cross-sectional view of the electrical component of FIG. 5, 8, or 9 after the gold alloy has been reflowed into the vias.

FIG. 11 is a schematic flow diagram depicting a method or process for forming the electrical component of FIG. 10.

### DETAILED DESCRIPTION

In general, the present disclosure provides various embodiments of an electrical component and a method of forming such electrical component. The electrical component may include a substrate that includes an outer surface. The electrical component may further include one or more vias disposed in the substrate. The one or more vias may each include a sidewall formed by the substrate and an opening at the outer surface of the substrate. An interface layer may be disposed on at least a portion of the sidewall of each of the one or more vias. A gold alloy may be disposed in the one or more vias and bonded to the interface layer of each of the one or more vias. The bond between the gold alloy and the interface layer may provide a hermetic seal. Furthermore, the methods of disposing and reflowing the gold alloy into the vias may reduce porosity and cracking of the via fill materials compared to existing via fill materials and methods. Accordingly, the electrical component described herein can be used as part of devices where corrosion resistance or long-term hermeticity is desired.

Although existing via fill materials such as, for example, copper-based alloys may exhibit good conductivity, such alloys are generally not corrosion resistant. Additionally, some copper-alloy filled vias may exhibit a level of porosity that may lead to long-term hermeticity failure. In contrast, the gold alloy filled vias described herein may form a bond between the sidewall formed by the substrate and the interface layer and a bond between the gold alloy fill material and the sidewall formed by the substrate. Additionally, such gold alloy filled vias may have reduced porosity and cracking of the via fill material.

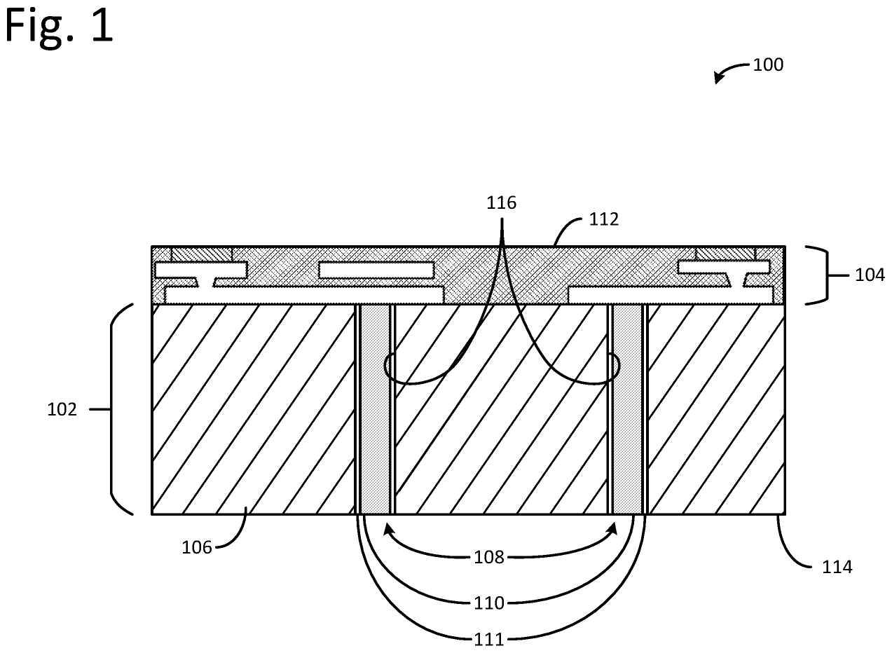

FIG. 1 shows a schematic cross-sectional view of a portion of an apparatus 100 that may be used in sealed packages. The apparatus 100 includes an electrical component 102 and a circuitry 104 disposed on the electrical component 102. The electrical component includes a substrate 106 with vias 108 disposed in the substrate 106. An interface layer 111 is disposed on sidewalls 116 of the vias 108. A gold alloy 110 is disposed in the vias 108 and may be bonded to the sidewalls 116 of the vias 108.

The substrate 106 may include any suitable material or materials such as, for example, ceramic, sapphire, glass, or a semiconductor. Ceramics may include, for example, alumina (Al₂O₃), nanocrystalline yttria-stabilized zirconia (nc-YSZ), or other corrosion-resistant ceramics. In at least one embodiment, the substrate 106 includes sapphire. In one or more embodiments, the substrate 106 can include a transparent material. The substrate 106 has a thickness that extends between an outer surface 112 and an outer surface 114. The outer surface 112 may be referred to interchangeably as a first major surface and the outer surface 114 may be referred to interchangeably as a second major surface. The substrate 106 may take on any suitable shape or shapes and have any suitable dimensions.

The vias 108 extend from the outer surface 112 to the outer surface 114 and are exposed at such surfaces. Accordingly, the electrical component 102 may be used as a feedthrough, an interposer, or other electrical component. The vias 108 may have any suitable cross-sectional shape or shapes. For example, the vias 108 may have an elliptical cross section. Such elliptical vias may have a single sidewall 116 that defines the outer diameter of the elliptical vias. Further, for example, the vias 108 may have a polygonal cross section. Such polygonal vias may have three or more sidewalls 116. Still further, for example, the vias 108 may have a cross-sectional shape that includes both straight and curved edges such as, for example, a semicircle, a quadrant, arcs, or combinations of curved and polygonal shapes. Vias with such cross-sectional shapes may include two or more sidewalls 116.

The interface layer 111 is disposed on the sidewalls 116 of the vias 108. The interface layer 111 may be bonded to the sidewalls 116 formed by the substrate 106. The interface layer 111 may include any suitable material or materials for bonding to the sidewalls 116 of the substrate 106 and the gold alloy 110. Such materials may include, titanium, niobium, gold, platinum, tantalum, zirconium, etc. The interface layer 111 may be corrosion resistant. As used herein, “corrosion resistant” or “corrosion-resistant” may refer to materials, alloys, vias, and layers that exhibit less than a 1 micrometer reduction in height of the outer surface when exposed to a 0.9 percent saline solution at 90 degrees Celsius for 10 weeks. In other words, a layer of material removed from corrosion-resistant materials, alloys, vias, or layers due to exposure to a 0.9 percent saline solution at 90 degrees Celsius for 10 weeks will have a thickness of less than 1 micrometer. In general, corrosion-resistant materials and devices remain chemically stable and resist break down or damage due to chemical processes in corrosive environments such as, e.g., marine environments, underground, in the body (e.g., biostable), etc. Accordingly, the interface layer 111 may not include alloys or compositions that may compromise a corrosion resistance of the interface layer 111. While not all alloys that include materials such as titanium, titanium, niobium, gold, platinum, tantalum, and zirconium are corrosion-resistant, corrosion-resistant alloys described herein, may refer to the subset of such materials and alloys that are corrosion resistant.

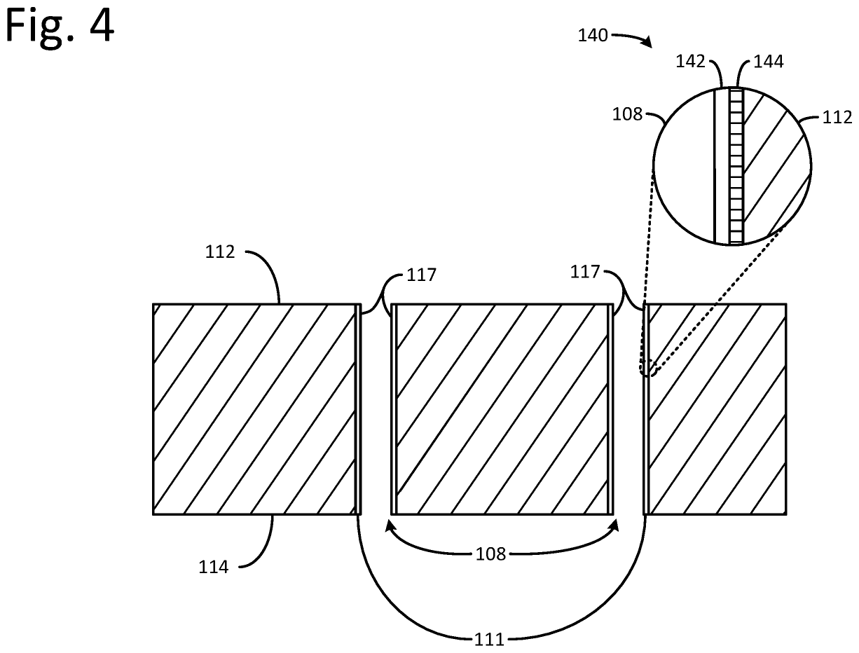

The interface layer 111 may also include materials that are not corrosion resistant. The inventors have found, surprisingly, that a portion of the interface layer 111 may include materials that are not corrosion resistant such as, for example, copper, and still result in corrosion-resistant and hermetically sealed vias using the methods and processes described herein. The inventors have found that during such processes, a portion of the interface layer 111 (e.g., wettable layer 142 of FIG. 4) may go into solution during reflow, incorporating the copper into corrosion-resistant materials and alloys such that exposed portions of via fill material are corrosion resistant.

The vias 108 are filled with the gold alloy 110. The gold alloy 110 may be bonded to the sidewalls 116. The vias 108 may be hermetically sealed by the interface layer 111 and the gold alloy 110. In other words, the bonds between the gold alloy 110, the interface layer 111, and the sidewalls 116 may provide a hermetic seal. The gold alloy 110 may include any suitable material or materials. Such materials may include one or more of, for example, titanium, tin, germanium, niobium, silicon, silver, tungsten, etc. In at least one embodiment, the gold alloy 110 includes Au-20Sn. In at least one other embodiment, the gold alloy 110 includes Au-12Ge. In at least one other embodiment, the gold alloy 110 includes AuSi. In at least one other embodiment, the gold alloy 110 includes titanium. In at least one other embodiment, the gold alloy 110 can include at least one of Au—Si—Sn or Au—Sn—Sb. In at least one embodiment, the gold alloy 110 can include at least one of Au-20Sb-4Sn (e.g., about 19-21 weight % of Sb and about 3.8-4.2 weight % of Sn), Au-18.5Sb-6In (e.g., about 17.6-19.4 weight % of Sb and about 5.7-6.3 weight % of In), Au-2.6Si-4.0Sn (e.g., about 2.5-2.7 weight % of Si and about 3.8-4.2 weight % of Sn), Au-2.2Si-6.0Sn (e.g., about 2.1-2.3 weight % of Si and about 5.7-6.3 weight % of Sn), or Au-2.8Si-2.0Sn (e.g., about 2.7-2.9 weight % of Si and about 1.9-2.1 weight % of Sn). The gold alloy 110 may be corrosion resistant. Accordingly, the gold alloy 110 may not include alloys or compositions that may compromise a biostability of the gold alloy 110. While not all alloys that include gold and other elements are corrosion resistant, the gold alloys described herein refer to the subset of such alloys that are corrosion resistant. Accordingly, vias, such as vias 108, that are filled with the gold alloy 110 and the interface layer 111 may be corrosion-resistant vias.

The circuitry 104 may include any suitable circuitry or components for incorporating the electrical component 102 in a device (e.g., an implantable medical device). The circuitry 104 may include, for example, multiple layers, substrates, conductive traces, vias, passive components, active components, pads, electrodes, or other electrical components. The circuitry 104 may be soldered or otherwise sealed to the substrate 106. The circuitry 104 may take on any suitable shape or shapes and have any suitable dimensions. Generally, the circuitry 104 may be shaped to fit in a housing of a device.

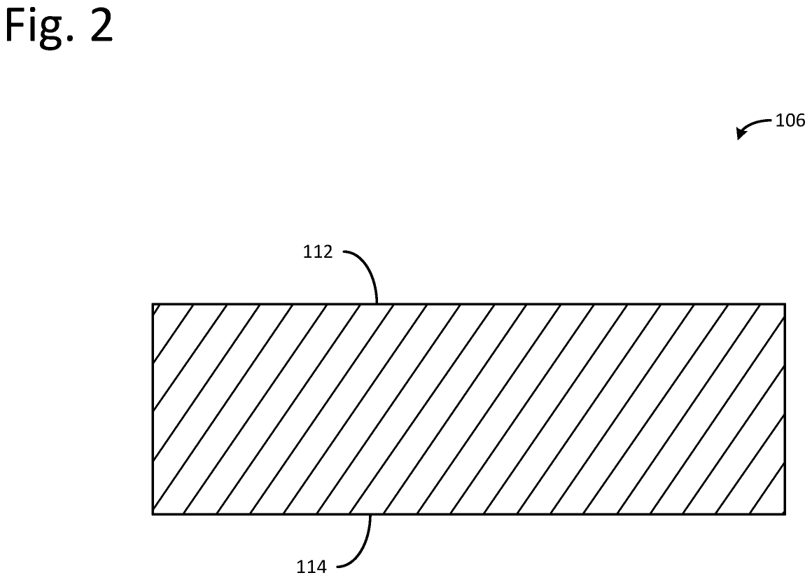

FIGS. 2-10 show various stages of various methods or processes of forming an electrical component such as, for example, electrical component 102. Although such methods and processes are described in reference to electrical component 102 of FIG. 1, the methods and processes may be used for any suitable electrical component that includes a substrate, one or more vias, and a gold alloy disposed in the vias.

FIG. 2 shows the substrate 106 provided prior to vias 108 being formed in the substrate. The substrate 106 extends between the outer surface 112 and the outer surface 114. The substrate may include ceramic or sapphire. Additionally, providing the substrate 106 may include any suitable preparatory steps such as, for example, shaping, grinding, or polishing the outer surfaces 112, 114 of the substrate 106.

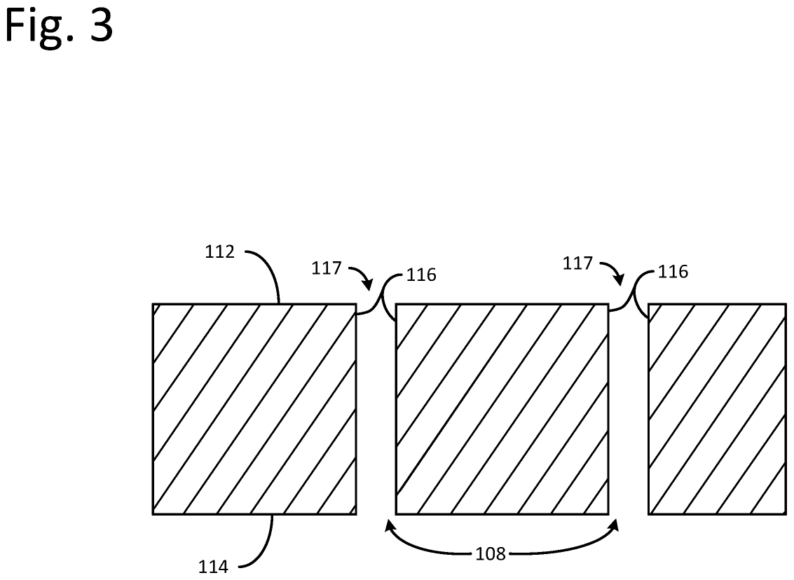

FIG. 3 shows the substrate 106 after the vias 108 have been formed. Each of the vias 108 include openings 117 and extend from an opening 117 at the outer surface 112 to an opening 117 at the outer surface 114. Additionally, the vias 108 include a sidewall 116 formed by the substrate 106. The vias 108 may be formed using any suitable technique or techniques. For example, the vias 108 may be formed by laser or mechanical drilling.

FIG. 4 shows the interface layer 111 disposed on the sidewall of the vias 108 of FIG. 3. The interface layer 111 may include a wettable layer 142 and an adhesion layer 144 as shown in the zoomed in portion 140. The adhesion layer 144 may be disposed on the sidewalls 116 of the vias 108 and the wettable layer 142 may be disposed on the adhesion layer 144. The adhesion layer 144 may include any suitable material or materials for bonding to the sidewalls 116 formed by the substrate 106 during a reflow process. For example, the adhesion layer 144 may include titanium, niobium, zirconium, tantalum, tungsten, or alloys thereof. The wettable layer 142 may include any suitable material or materials for bonding the gold alloy 110 to the interface layer 111 during a reflow process. For example, the wettable layer 142 may include gold, copper, platinum, palladium, silver, nickel, or alloys thereof. Copper or other non-corrosion-resistant materials of the wettable layer 142 may be included in the wettable layer 142 at levels that allow such non-corrosion-resistant materials to go into solution and be incorporated into the corrosion-resistant materials such that the formed vias remain corrosion resistant. In one at least one embodiment, copper or other non-corrosion-resistant materials of the wettable layer 142 may be less than 20 atomic percent of total via fill materials (e.g., the interface layer 111 and the gold alloy 110) of the vias 108. In one at least one embodiment, copper or other non-corrosion-resistant materials of the wettable layer 142 may be less than 15 atomic percent of total via fill materials (e.g., the interface layer 111 and the gold alloy 110) of the vias 108. In at least one embodiment, copper or other non-corrosion-resistant materials of the wettable layer 142 may be less than 5 atomic percent of total via fill materials of the vias 108. In one at least one embodiment, copper or other non-corrosion-resistant materials of the wettable layer 142 may be less than 12 atomic percent of total via fill materials (e.g., the interface layer 111 and the gold alloy 110) of the vias 108. In one at least one embodiment, copper or other non-corrosion-resistant materials of the wettable layer 142 may be less than 10 atomic percent of total via fill materials (e.g., the interface layer 111 and the gold alloy 110) of the vias 108. Additionally, the wettable layer 142 and the adhesion layer 144 may be configured to bond to each other during deposition.

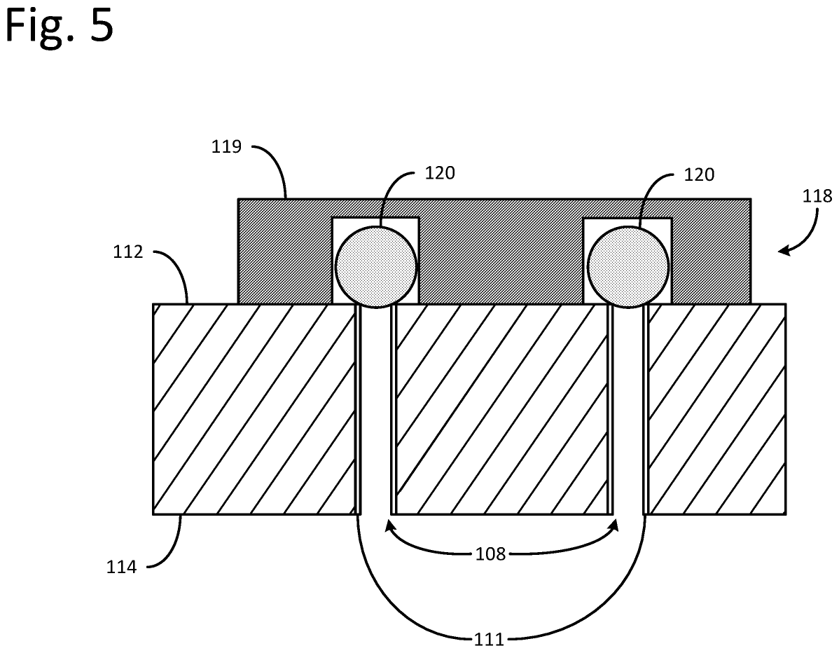

FIG. 5 shows a bump array 118 being used to dispose the gold alloy 110 on the substrate 106. The bump array 118 includes a stencil or base 119 and alloy bumps 120. The stencil 119 may be used to secure the position of the alloy bumps 120 relative to the vias 108 prior to a reflowing process. The stencil 119 may include any suitable materials such as, for example, graphite, silicon, stainless steel, anodized aluminum, etc. In at least one embodiment, the stencil 119 includes a graphite sheet.

The alloy bumps 120 include the gold alloy 110. The alloy bumps 120 may further include any suitable material or materials to aid a reflow process. For example, the alloy bumps 120 may include flux, organic binders, fluid, etc. Such materials may aid the gold alloy 110 in filling the vias 108 and bonding to the sidewalls 116. The alloy bumps 120 may take one any suitable shape or shapes. For example, the alloy bumps 120 may be substantially spherical, discoid, parallelepiped, hemispherical, or other suitable shape. Each of the alloy bumps 120 may be of a size sufficient to fill the vias 108 during a reflow process.

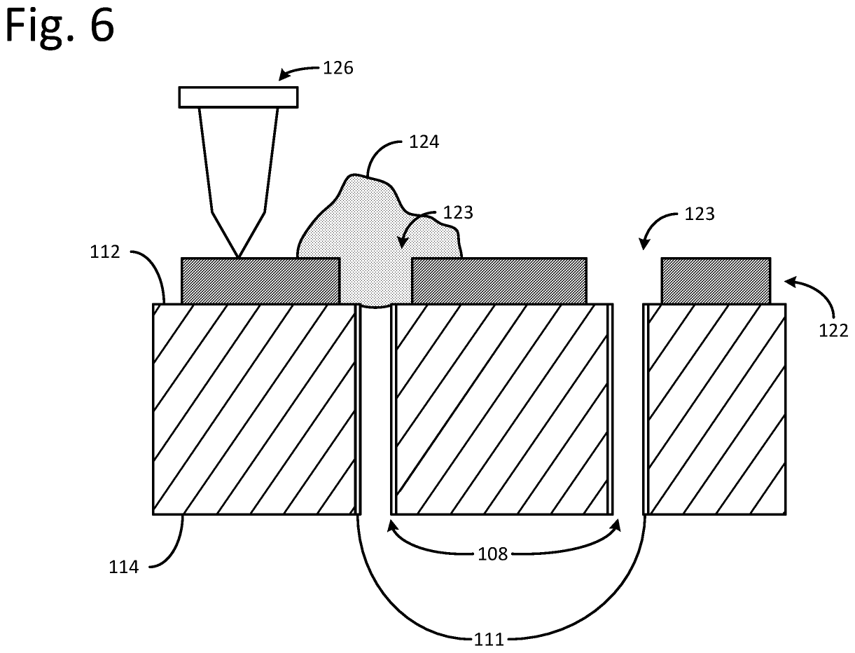

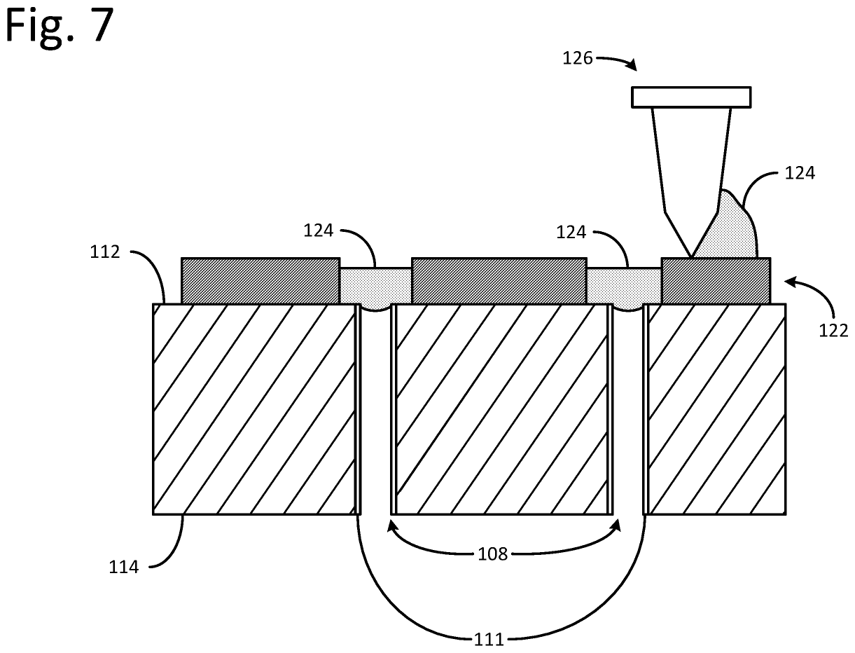

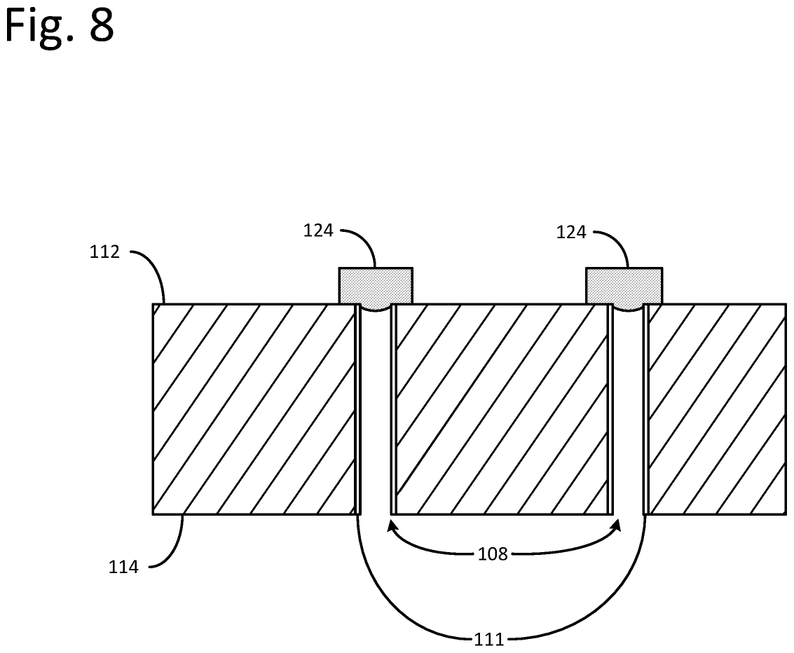

FIGS. 6-8 show a stencil-printing process being used to dispose the gold alloy 110 on the substrate 106. The stencil-printing process may include positioning a stencil 122 on the outer surface 112 of the substrate 106, disposing alloy paste 124 at one side of the stencil 122, pulling the alloy paste 124 across the stencil 122 and the substrate 106, and removing the stencil 122 from the substrate 106. FIG. 6 shows the stencil-printing process after the alloy paste 124 has been disposed but before the paste has been pulled across the stencil 122 and the substrate 106. FIG. 7 shows the stencil-printing process after the alloy paste 124 has been pulled across the stencil 122 and the substrate 106 but before the stencil has been removed from the substrate 106. FIG. 8 shows the substrate 106 and the alloy paste 124 after the stencil has been removed and the stencil-printing process is complete.

The stencil 122 may be used to position the alloy paste 124 relative to the vias 108 prior to a reflowing step or process. For example, the stencil 122 may include openings 123 at or near the position of the vias 108. The openings 123 may allow the alloy paste 124 to be deposited in the vias 108 or on the outer surface 112 of the substrate 106 proximal to the vias 108. The stencil 122 may include any suitable materials such as, for example, stainless steel, nickel, etc. In at least one embodiment, the stencil 119 includes stainless steel.

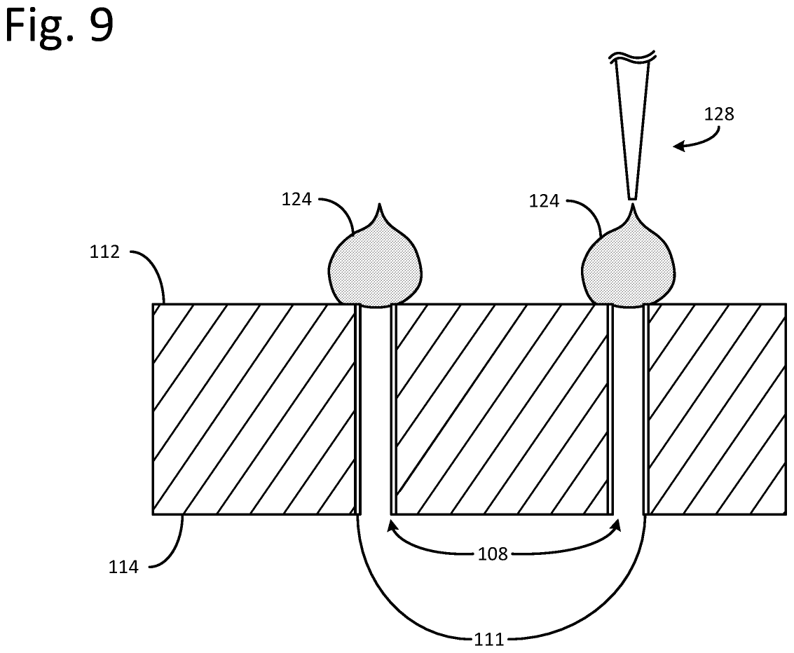

The alloy paste 124 may include the gold alloy 110. The gold alloy 110 may be included in the alloy paste 124 as alloy particles. The alloy paste 124 can include binding agents to hold the alloy particles together. The alloy paste 124 can include any suitable binding agents, e.g., organic binders, solvents, etc. The alloy paste 124 can be dispensed using any suitable dispensing tools and/or nozzles such as, for example, dispenser 128 (see FIG. 9).

The alloy paste 124 can be pulled across the stencil 122 and the substrate 106 using any suitable tool or tools. For example, the alloy paste 124 can be pulled across the stencil 122 and the substrate 106 using a squeegee 126. The squeegee 126 may be configured to pull the alloy paste 124 across the stencil 122 and the substrate 106 causing the alloy paste 124 to be deposited in the openings 123 of the stencil 122. After the alloy paste 124 has been deposited in the openings 123 of the stencil 122, the stencil 122 can be removed from the outer surface 112 of the substrate 106 leaving the alloy paste 124 positioned in and proximal to the vias 108. Accordingly, the substrate 106 and the alloy paste 124 of FIG. 8 may be ready for a reflow process for reflowing the gold alloy 110 into the vias 108.

FIG. 9 shows a dispensing process being used to dispose the gold alloy 110 on the substrate 106. As shown, the dispenser 128 is used to dispense alloy paste 124 onto the substrate 106 proximal to, over, and in the vias 108. The dispenser 128 may be configured to dispense an amount of the alloy paste 124 sufficient to fill the vias 108 with the gold alloy 110 during a reflow process. Accordingly, the substrate 106 and the alloy paste 124 of FIG. 9 may be ready for a reflow process for reflowing the gold alloy 110 into the vias 108.

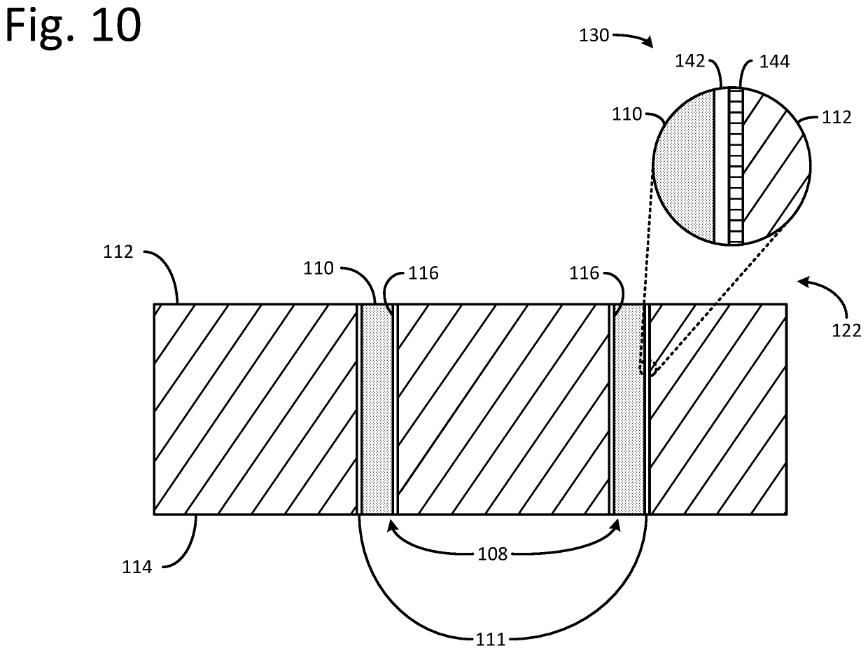

FIG. 10 shows the electrical component 102 after reflowing the gold alloy 110 into the vias 108. The gold alloy 110 filling the vias 108 as depicted in FIG. 10 can be produced by reflowing the alloy bumps 120 of FIG. 4 or the alloy paste 124 of FIGS. 5-8. The interface layer 111 includes the adhesion layer 144 bonded to the substrate 106 and the wettable layer 142 disposed on and bonded the adhesion layer 144 as shown in zoomed portion 130. The bond between the adhesion layer 144 and the substrate 106 may be a covalent bond. In contrast, the bond between the wettable layer 142 and the adhesion layer 144 may be a metallic bond. Such bonds may provide a hermetic seal.

Additionally, the gold alloy 110 may bond with the adhesion layer 142. The wettable layer 142 may be configured to bond to the gold alloy 110 during a reflow process. Accordingly, the gold alloy 110, the interface layer 111, and the sidewalls 116 may be bonded together to form a hermetic seal.

Still further, during the reflow process, the wettable layer 142 may go into solution. In other words, the wettable layer 142 may diffuse and mix with the gold alloy 110 and any materials of the wettable layer 142 may be incorporated into the gold alloy 110 during reflow. Accordingly, in embodiments where the wettable layer 142 includes materials that are not corrosion resistant such as, for example, copper. Such non-corrosion-resistant materials may be incorporated into the gold alloy 110 during a reflow process to form a corrosion-resistant via.

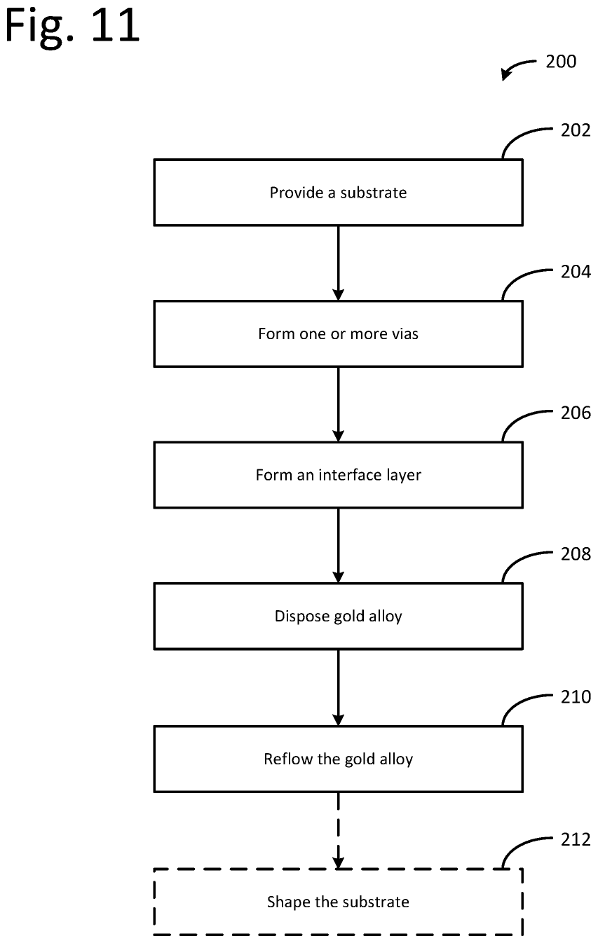

FIG. 11 shows a schematic flow diagram of a method or process 200 for forming an electrical component such as, for example, electrical component 102. Although described in reference to electrical component 102 of FIGS. 1 and 10, the process 200 may be used for any suitable electrical component that includes a substrate, one or more vias, and a gold alloy disposed in the vias.

At 202, the substrate 106 may be provided (see FIG. 2). The substrate may include ceramic, sapphire, glass, or semiconductor materials. Providing the substrate 106 may include shaping, grinding, or polishing to form the outer surface 112 and the outer surface 114.

At 204, one or more vias 108 may be formed in the substrate 106 (see FIG. 3). Each of the one or more vias 108 may include an opening 117 at an outer surface 112 of the substrate 106. Additionally, each of the one or more vias 108 may include a sidewall 116 formed by the substrate 106. The one or more vias 108 may be formed using any suitable technique or techniques. For example, the one or more vias may be formed using laser or mechanical drilling.

At step 206, the interface layer 111 may be formed on at least a portion of the sidewall 116 of each of the one or more vias 108. The interface layer 111 may be formed using any suitable technique or techniques. For example, the interface layer 111 may be formed using sputtering, physical vapor deposition, chemical vapor deposition, atomic layer deposition, or plating (e.g., electroplating or electroless plating). The interface layer 111 may be formed in stages or layers. For example, the adhesion layer 144 may be formed on at least a portion of the sidewall 116 of each of the one or more vias 108. The adhesion layer 144 may be formed using sputtering. Furthermore, the wettable layer 142 may be formed on the adhesion layer 144. The wettable layer 142 may be formed using, for example, physical vapor deposition, chemical vapor deposition, atomic layer deposition, or plating (e.g., electroplating or electroless plating). Each of the wettable layer 142 and the adhesion layer 144 may be formed using any suitable technique or techniques as described above with regard to the interface layer 111. Additionally, the wettable layer 142 may also be formed by plating.

At step 208, the gold alloy 110 may be disposed in the one or more vias 108 or on the outer surface 112 of the substrate 106 proximal to the one or more vias 108. As used herein, the term “proximal to the one or more vias” means that the gold alloy 110 is disposed such that at least a portion of the alloy can flow into one or more openings 117 of the one or more vias 108 when the gold alloy is melted. Additionally, the gold alloy may be disposed on the outer surface 112 of the substrate such that the opening 117 of each of the one or more vias 108 is at least partially covered by the gold alloy 110.

The gold alloy 110 may be disposed using any suitable technique or techniques. For example, disposing the gold alloy may include, but is not limited to, disposing a bump array 118 of the gold alloy 110 on the outer surface 112 of the substrate 106 such that the opening 117 of each of the one or more vias 108 is at least partially covered by an alloy bump 120 of the bump array 118 (see FIG. 5). The alloy bumps 120 can be held in place using any suitable technique. In one or more embodiments, the alloy bumps 120 of the bump array 118 may be held in place by a stencil 119 while the bump array 118 is disposed on the outer surface 112 of the substrate 106. In one or more embodiments, the alloy bumps 120 can be held in place, e.g., with flux, paste, fluid, etc. Further, for example, disposing the gold alloy 110 may include stencil-printing alloy paste 124 including the gold alloy 110 in the one or more vias 108 or on the outer surface 112 of the substrate 106 proximal to the one or more vias 108 (see FIGS. 6-8). Still further, for example, disposing the gold alloy comprises dispensing an alloy paste comprising the gold alloy in the one or more vias or on the outer surface of the substrate proximal to the one or more vias (see FIG. 9). Additionally, other techniques for disposing via fill material may be used to dispose the gold alloy 110 in the one or more vias 108 or on the outer surface 112 of the substrate 106 proximal to the one or more vias 108.

At 210, the gold alloy 110 may be reflowed into the one or more vias 108. Reflowing the gold alloy 110 may include reducing an atmospheric pressure around the substrate 106 and the gold alloy 110. The atmospheric pressure may be reduced to any suitable level, for example, to less than 10⁻³ Torr. In one or more embodiments, the atmospheric pressure may not be reduced.

Reflowing the gold alloy 110 may include brazing the substrate 106 and the gold alloy 110. Reflowing the gold alloy 110 may include heating the substrate 106 and the gold alloy 110 to a peak temperature. Peak temperatures for reflowing the gold alloy 110 may be based on a melting temperature (Tm) of the gold alloy 110. The melting temperature (Tm) may also be referred to as the eutectic temperature (TE). Reflowing the gold alloy 110 may include heating the substrate 106 and the gold alloy 110 to a peak temperature, for example, of at least 10 degrees Celsius greater than the melting temperature of the gold alloy 110 and no greater than 100 degrees Celsius greater than the melting temperature of the gold alloy 110 or to a peak temperature within any suitable range therebetween. For example, reflowing the gold alloy 110 may include heating the substrate 106 and the gold alloy 110 to a peak temperature of at least 10 degrees Celsius, 15 degrees Celsius, 20 degrees Celsius, 25 degrees Celsius, 30 degrees Celsius, 35 degrees Celsius, or 40 degrees Celsius greater than the melting temperature of the gold alloy 110 to no greater than 70 degrees Celsius, 75 degrees Celsius, 80 degrees Celsius, 85 degrees Celsius, 90 degrees Celsius, 95 degrees Celsius, or 100 degrees Celsius greater than the melting temperature of the gold alloy 110. In one embodiment, reflowing the gold alloy 110 may include heating the substrate 106 and the gold alloy 110 to a peak temperature of at least 30 degrees Celsius greater than the melting temperature of the gold alloy 110 and no greater than 100 degrees Celsius greater than the melting temperature of the gold alloy 110.

Reflowing the gold alloy 110 may include heating the substrate 106 and the gold alloy 110 to a peak temperature independent of the melting temperature. In at least one embodiment, reflowing the gold alloy 110 includes heating the gold alloy 110 to a peak temperature of at least 330 degrees Celsius and no greater than 390 degrees Celsius. The substrate 106 and the gold alloy 110 may be heated at the peak temperature for at least 10 seconds and no greater than 30 minutes or for any suitable range of time therebetween. For example, the substrate 106 and the gold alloy 110 may be heated at the peak temperature in a range from at least 10 seconds, 20 seconds, 30 seconds, 40 seconds, 50 seconds, 1 minute to no greater than 3 minutes, 5 minutes, 10 minutes, 15 minutes, 20 minutes, 25 minutes, or 30 minutes. In at least one embodiment, the gold alloy 110 may be heated at the peak temperature for at least 1 minute and no greater than 15 minutes.

Reflowing the gold alloy 110 may include filling a volume surrounding the substrate 106 and the gold alloy 110 with an inert gas. In one or more embodiments, the volume surrounding the substrate 106 and the gold alloy 110 can be filled with one or more active gases, e.g., at least one of H₂, CH₃COOH, or CO. In one or more embodiments, the volume can be filled with at least one inert gas and at least one active gas. The volume may include an inner volume of a furnace for heating the substrate 106 and the gold alloy 110. The inert gas may include, for example, argon, nitrogen, Diazene (N₂H₂), or mixtures thereof. In at least one embodiment, the inert gas includes argon.

At 212, the substrate 106 may be shaped. Shaping the substrate 106 may include grinding or polishing one or more surfaces of the substrate 106. Additionally, shaping of the substrate 106 may include grinding or polishing the one or more vias 108. Shaping the substrate 106 may smooth portions of the outer surfaces 112, 114 of the substrate 106 and/or the one or more vias 108. Shaping the substrate 106 may result in one or more planar or curved surfaces.

The invention is defined in the claims. However, below there is provided a non-exhaustive listing of non-limiting examples. Any one or more of the features of these examples may be combined with any one or more features of another example, embodiment, or aspect described herein.

Example Ex1. A method of forming an electrical component. The method includes providing a substrate and forming one or more vias in the substrate. Each of the one or more vias includes an opening at an outer surface of the substrate and a sidewall. The method further includes forming an interface layer on at least a portion of the sidewall of each of the one or more vias and disposing gold alloy in the one or more vias or on the outer surface of the substrate proximal to the one or more vias. The method further includes reflowing the gold alloy into the one or more vias to form one or more corrosion-resistant vias such that the interface layer is disposed between the gold alloy and the sidewall of each of the one or more vias.

Example Ex2. The method of Ex1, where disposing the gold alloy includes disposing a bump array of the gold alloy on the outer surface of the substrate such that the opening of each of the one or more vias is at least partially covered by an alloy bump of the bump array.

Example Ex3. The method of Ex2, where alloy bumps of the bump array are held in place by a stencil while the bump array is disposed on the outer surface of the substrate.

Example Ex4. The method of Ex1, where disposing the gold alloy includes stencil printing alloy paste that includes the gold alloy in the one or more vias or on the outer surface of the substrate proximal to the one or more vias.

Example Ex5. The method of Ex1, where disposing the gold alloy includes dispensing an alloy paste that includes the gold alloy in the one or more vias or on the outer surface of the substrate proximal to the one or more vias.

Example Ex6. The method of Ex1, where reflowing the gold alloy includes reducing an atmospheric pressure around the substrate and the gold alloy.

Example Ex7. The method of Ex6, where the atmospheric pressure is reduced to less than 10⁻³ Torr.

Example Ex8. The method of Ex1, where reflowing the gold alloy includes heating the substrate and the gold alloy to a peak temperature of at least 30 degrees Celsius greater than a melting temperature of the gold alloy and no greater than 100 degrees Celsius greater than the melting temperature of the gold alloy.

Example Ex9. The method of Ex8, where the substrate and the gold alloy are heated at the peak temperature for at least 1 minute and no greater than 15 minutes.

Example Ex10. The method of Ex1, where reflowing the gold alloy includes filling a volume surrounding the substrate and the gold alloy with an inert gas.

Example Ex11. The method of Ex1, where the interface layer includes titanium.

Example Ex12. The method of Ex1, where forming the interface layer includes depositing the interface layer using atomic layer deposition.

Example Ex13. The method of Ex1, where forming the interface layer includes sputtering the interface layer.

Example Ex14. The method of claim 1, where forming the interface layer includes forming an adhesion layer on the at least the portion of the sidewall of each of the one or more vias, and forming a wettable layer on the adhesion layer.

Example Ex15. The method of Ex1, where reflowing the gold alloy hermetically seals the one or more vias.

Example Ex16. An electrical component that includes a substrate and one or more corrosion-resistant vias. The substrate includes an outer surface. The one or more corrosion-resistant vias are disposed in the substrate. Each of the one or more corrosion-resistant vias include a sidewall formed by the substrate and an opening at the outer surface of the substrate. The interface layer is disposed on at least a portion of the sidewall of each of the one or more corrosion-resistant vias. The gold alloy is bonded to the interface layer.

Example Ex17. The electrical component of Ex16, where the interface layer includes an adhesion layer bonded to the substrate, and a wettable layer disposed on the adhesion layer.

Example Ex18. The electrical component of Ex17, where the wettable layer includes copper and is incorporated into the gold alloy.

Example Ex19. The electrical component of Ex17, where the wettable layer includes one or more of gold, platinum, palladium, or silver.

Example Ex20. The electrical component of Ex17, where the adhesion layer includes one or more of titanium, tungsten, niobium, zirconium, or tantalum.

Example Ex21. The electrical component of Ex16, where the one or more corrosion-resistant vias are hermetically sealed by the interface layer and the gold alloy.

Example Ex22. The electrical component of Ex16, where the substrate includes sapphire.

All references and publications cited herein are expressly incorporated herein by reference in their entirety into this disclosure, except to the extent they may directly contradict this disclosure. Illustrative embodiments of this disclosure are discussed, and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

What is claimed is:

1. A method comprising:
providing a substrate;
forming one or more vias in the substrate, each of the one or more vias comprising an opening at an outer surface of the substrate and a sidewall;
forming an interface layer on at least a portion of the sidewall of each of the one or more vias;
disposing gold alloy in the one or more vias or on the outer surface of the substrate proximal to the one or more vias; and
reflowing the gold alloy into the one or more vias to form one or more corrosion-resistant vias such that the interface layer is disposed between the gold alloy and the sidewall of each of the one or more vias.

2. The method of claim 1, wherein disposing the gold alloy comprises disposing a bump array of the gold alloy on the outer surface of the substrate such that the opening of each of the one or more vias is at least partially covered by an alloy bump of the bump array.

3. The method of claim 2, wherein alloy bumps of the bump array are held in place by a stencil while the bump array is disposed on the outer surface of the substrate.

4. The method of claim 1, wherein disposing the gold alloy comprises stencil printing alloy paste comprising the gold alloy in the one or more vias or on the outer surface of the substrate proximal to the one or more vias.

5. The method of claim 1, wherein disposing the gold alloy comprises dispensing an alloy paste comprising the gold alloy in the one or more vias or on the outer surface of the substrate proximal to the one or more vias.

6. The method of claim 1, wherein reflowing the gold alloy comprises reducing an atmospheric pressure around the substrate and the gold alloy.

7. The method of claim 6, wherein the atmospheric pressure is reduced to less than 10⁻³ Torr.

8. The method of claim 1, wherein reflowing the gold alloy comprises heating the substrate and the gold alloy to a peak temperature of at least 30 degrees Celsius greater than a melting temperature of the gold alloy and no greater than 100 degrees Celsius greater than the melting temperature of the gold alloy.

9. The method of claim 8, wherein the substrate and the gold alloy are heated at the peak temperature for at least 1 minute and no greater than 15 minutes.

10. The method of claim 1, wherein reflowing the gold alloy comprises filling a volume surrounding the substrate and the gold alloy with an inert gas.

11. The method of claim 1, wherein the interface layer comprises titanium.

12. The method of claim 1, wherein forming the interface layer comprises depositing the interface layer using atomic layer deposition.

13. The method of claim 1, wherein forming the interface layer comprises sputtering the interface layer.

14. The method of claim 1, wherein forming the interface layer comprises:
forming an adhesion layer on the at least the portion of the sidewall of each of the one or more vias; and
forming a wettable layer on the adhesion layer.

15. The method of claim 1, wherein reflowing the gold alloy hermetically seals the one or more vias.

16. An electrical component comprising:
a substrate;
one or more corrosion-resistant vias disposed in the substrate, each of the one or more corrosion-resistant vias comprising:
one or more sidewalls formed by the substrate;
an interface layer disposed on at least a portion of the one or more sidewalls; and
gold alloy bonded to the interface layer.

17. The electrical component of claim 16, wherein the interface layer comprises:
an adhesion layer bonded to the substrate; and
a wettable layer disposed on the adhesion layer.

18. The electrical component of claim 17, wherein the wettable layer comprises copper and is incorporated into the gold alloy.

19. The electrical component of claim 17, wherein the wettable layer comprises one or more of gold, platinum, palladium, or silver.

20. The electrical component of claim 17, wherein the adhesion layer comprises one or more of titanium, tungsten, niobium, zirconium, or tantalum.

21. The electrical component of claim 16, wherein the one or more corrosion-resistant vias are hermetically sealed by the interface layer and the gold alloy.

22. The electrical component of claim 16, wherein the substrate comprises sapphire.
